(19) United States
(12) Patent Application Publication
(10) Pub. No.: US 2006/0099819 A1
(43) Pub. Date: May 11, 2006

(54) Low dielectric constant compositions and methods of use thereof

(75) Inventors: Leonard V. Interrante, Schenectady, NY (US); Zhizhong Wu, Cambridge, MA (US); Pei-I Wang, Troy, NY (US); Toh-Ming Lu, Loudonville, NY (US)

Correspondence Address: HESLIN ROTHENBERG FARLEY & MESITI PC, 5 COLUMBIA CIRCLE, ALBANY, NY, 12203, US

(73) Assignee: Rensselaer Polytechnic Institute, Troy, NY (US)

(21) Appl. No.: 11/219,211

(22) Filed: Sep. 2, 2005

Related U.S. Application Data
(60) Provisional application No. 60/607,102, filed on Sep. 3, 2004.

(51) Int. Cl. H01L 21/31

(52) U.S. Cl. 438/758

(57) ABSTRACT

Low dielectric compositions and methods of use thereof in integrated circuits are disclosed. The low dielectric compositions are derived from carbosilane polymers and oligomers containing imbedded sila- or disilacyclobutane rings and, after heating to induce cross-linking, may be used as an interlayer dielectric as well as a capping layer within an integrated circuit.

### CROSS-REFERENCE TO RELATED APPLICATION

This application claims priority from U.S. Provisional Application Ser. No. 60/607,102, filed Sep. 3, 2004, the entire contents of which are incorporated herein by reference.

### FIELD OF THE INVENTION

The invention relates to low dielectric compositions, methods of use thereof in integrated circuits.

### BACKGROUND OF THE INVENTION

The growth of Integrated Circuit (IC) technology is primarily based on the continued scaling of devices to ever-smaller dimensions. Smaller devices provide higher packing density and higher operating speed. In the ultra-large-scale integration (ULSI) era, millions, and soon to be billions, of transistors on a chip must be interconnected to give desired functions. As minimum device features shrink below 0.25 microns, the increase in propagation delay, cross-talk noise and power dissipation of the interconnect structure become limiting factors. It is therefore, essential to reduce the interconnect capacitance in order to maintain the trend of reduced delay time, reduced power consumption and reduced noise for future scaled devices. Capacitance is directly proportional to dielectric constant (k). Currently the most common semiconductor dielectric is silicon dioxide, which has a dielectric constant of about 4.0. Thus there is substantial interest in materials with low value of dielectric constant that can replace silicon dioxide based insulators as Interlayer Dielectrics (ILD).

One problem with essentially all candidates for low-k dielectrics is that copper has a relatively high diffusion coefficient in them, particularly when such dielectrics are rendered porous as a means of lowering the effective dielectric constant. When the copper layers are contacted with the dielectric layer, the copper will diffuse into the dielectric layer under an electrical bias at an elevated temperature, and will degrade the performance of the device. In order to prevent the copper diffusion problem, a barrier layer between the copper and the dielectric is generally required. The additional layer adds to the cost of processing, occupies valuable space, and requires an even lower dielectric constant for the dielectric material that is used in conjunction with such a barrier layer in order to meet the above requirements for the effective dielectric constant of the material between the copper interconnects.

Thus, a need exists for low dielectric compositions that overcome at least one of the aforementioned deficiencies.

### SUMMARY OF THE INVENTION

An aspect of the present invention relates to a method for providing an interlayer dielectric comprising:

(a) applying a precursor mixture comprising:
(i) a polymeric or oligomeric carbosilane of the formula [cyclo-{R¹Si(CH₂)₂SiR²}—(CH₂)ₙ] wherein
   R¹ is an alkyl, an aryl, or a substituted alkyl or aryl,
   R² is an alkyl, an aryl, or a substituted alkyl or aryl,
   n is 1-10,
   m is >10 and typically >100, and, optionally,
(ii) a solvent,

to an integrated circuit component; and

(b) heating said precursor to form an interlayer dielectric. The resulting dielectric contains mainly or entirely C—H, C—C, and Si—C bonds. When solvent is employed, an additional step of heating to volatize the solvent may be interposed.

A second aspect of the present invention is a method for capping an integrated circuit component comprising:

(a) applying a precursor mixture comprising:
(i) a polymeric or oligomeric carbosilane of the formula [cyclo-{R¹Si(CH₂)₂SiR²}—(CH₂)ₙ]ₘ wherein
   R¹ is an alkyl, an aryl, or a substituted alkyl or aryl,
   R² is an alkyl, an aryl, or a substituted alkyl or aryl,
   n is 1-10,
   m is >10 and typically >100, and, optionally,
(ii) a solvent,

to at least one surface of an integrated circuit component containing a non-carbosilane dielectric; and

(b) heating the precursor to form an interlayer dielectric. The resulting capping layer contains mainly or entirely, C—H, C—C, and Si—C bonds. When solvent is employed, an additional step of heating to volatize the solvent may be interposed.

A third aspect of the present invention is an integrated circuit comprising an integrated circuit component and an interlayer dielectric resultant from the above processes.

A fourth aspect of the present invention is an integrated circuit comprising an integrated circuit component having an interlayer dielectric on at least one surface of the integrated circuit component. The interlayer dielectric comprises a cross-linked carbosilane having mainly or entirely C—H, C—C, and Si—C bonds. The dielectric is derived by thermally-induced opening of a precursor polymer or oligomer containing sila- or disilacyclobutane rings. A preferred embodiment of this carbosilane is derived from heating of a cyclolinear carbosilane precursor and has the general formula: 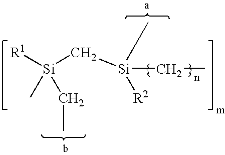
wherein
R¹ is an alkyl, an aryl, or a substituted alkyl or aryl, preferably methyl;
R² is an alkyl, an aryl, or a substituted alkyl or aryl, preferably methyl;
n is 1-10;
m is >10 and typically >100; and
a and b are points of crosslinking.

### BRIEF DESCRIPTION OF THE DRAWINGS

FIG. 1 depicts a plot of the capacitance as a function of Al electrode area for a dielectric measurement of the cured polymer, in accordance with the present invention;

FIG. 2 depicts a plot of current density vs applied field for the polymer film in accordance with the present invention; and

FIG. 3 depicts two plots of a copper/polycarbosilane (PCS) capacitor stressed at two different temperatures in accordance with the present invention; and

FIG. 4 depicts two stress plots of a capacitor having a PCS capping layer and a capacitor without the PCS capping layer in accordance with the present invention.

### DETAILED DESCRIPTION OF THE INVENTION

Definitions

Throughout this specification the terms and substituents retain their definitions.

The term alkyl is intended to include a linear, a branched, or a cyclic hydrocarbon structure, and combinations thereof. A lower alkyl refers to alkyl groups having from about 1 to about 6 carbon atoms. Examples of lower alkyl groups include but are not limited to methyl, ethyl, n-propyl, isopropyl, and n-, s- and t-butyl, and the like. A cycloalkyl is a subset of alkyl and includes cyclic hydrocarbon groups having from about 3 to about 8 carbon atoms. Examples of cycloalkyl groups include but are not limited to cyclopropyl, cyclobutyl, cyclopentyl, cyclohexyl, and the like. Typical alkyl groups are those of C₂₀ or below in an embodiment of the present invention.

Aryl means a 6-membered aromatic ring or fused rings. Examples of aryl groups include but are not limited to phenyl, napthyl, and the like. Substituted refers to an alkyl or an aryl wherein one or more of the hydrogen atoms of the aforementioned groups are replaced with an alkyl, an aryl, a halogen, and the like. Examples of a substituted aryl include but are not limited to toluene, xylene, a halogenated tolyl such as C₆H₄CH₂Br, and the like. Benzyl, for the purpose of the present invention, is included within the term substituted alkyl, in that it is an alkyl (methyl) substituted with an aryl (phenyl).

An integrated circuit (IC) component is an element of an IC. Examples of an IC component include, but are not limited to, an interconnected semiconductor device such as a transistor or a resistor; a copper interconnect; an aluminum interconnect; a porous or non-porous low k dielectric material; an insulating layer, a barrier layer, a wafer comprising a semiconducting material such as silicon, doped silicon, silicon on sapphire, gallium arsenide; and the like.

A method for providing an interlayer dielectric is presented in accordance with the present invention. The method comprises applying a carbosilane precursor mixture to an integrated circuit (IC) component and heating the precursor to form an interlayer dielectric. In an embodiment of the present invention, the precursor mixture comprises (i) a polymer or oligomeric carbosilane of the formula [cyclo-{R¹Si(CH₂)₂SiR²}-(CH₂)ₙ]ₘ wherein R¹ is an alkyl, an aryl, or a substituted aryl, R² is an alkyl, an aryl, or a substituted aryl, n is 1-10, m is >10 and typically >100, and, optionally, (ii) a solvent. The substituents R¹ and R² may be chosen independent of each other. In an embodiment of the present invention, R¹ is the same as R².

Examples of R¹ and R² substituents include but are not limited to a methyl group, a phenyl group, a tolyl group, a brominated tolyl group (—C₆H₄CH₂Br), and the like. The aforementioned described examples of substitutents are not meant to limit the scope of the polymer subtitutents and the subsequent polymer that may be used in accordance with the present invention.

Examples of a solvent used in the polymer mixture include but are not limited to xylene, hexane, tetrahydrofuran, chloroform, toluene, ethylene glycol dimethylether, and the like.

In an embodiment of the present invention the polymer mixture is applied to an IC component via a spin coating or other casting technique. Examples of IC components that may have the precursor mixture applied thereon include but are not limited to a transistor or a resistor; a copper interconnect; an aluminum interconnect, an insulating layer, a barrier layer, a silicon wafer, a doped silicon wafer, a silicon on sapphire wafer, and a gallium arsenide wafer.

Subsequent to application of the polymer mixture, the polymer mixture is heated at a temperature range from about 200° C. to about 450° C. for about 6 hr to about 9 hr to form interlayer dielectric. The formed interlayer dielectric is the cured/cross-linked carbosilane derived from heating the carbosilane precursor. An intermediary heating step may be inserted or performed before the aforementioned heating to drive off solvent and/or induce cross-linking. The intermediary heat may be performed at a temperature range from about 120° C. to about 150° C. for a time period of about 20 min to about 45 min.

A method for capping an integrated circuit component is presented in accordance with the present invention. The method comprises applying a carbosilane precursor mixture to at least one surface of an integrated circuit (IC) component and heating the polymer mixture to form a capping layer. In an embodiment of the present invention, the polymer mixture comprises (i) a polymeric or oligomeric carbosilane of the formula [Cyclo-{R¹Si(CH₂)₂SiR²}—(CH₂)ₙ]ₘ wherein R¹ is an alkyl, an aryl, or a substituted aryl, R² is an alkyl, an aryl, or a substituted aryl, n is 1-10, m is m is >10 and typically >100, and, optionally, (ii) a solvent. The substituents R¹ and R² may be chosen independent of each other. In an embodiment of the present invention, R¹ is the same as R².

Examples of R¹ and R² substituents include but are not limited to a methyl group, a phenyl group, a tolyl group, a brominated tolyl group (—C₆H₄CH₂Br), and the like. The aforementioned described examples of substituents are not meant to limit the scope of the carbosilane substituents and the subsequent cross-linked carbosilane that may be used in accordance with the present invention.

Examples of a solvent used in the precursor mixture include but are not limited to xylene, hexane, tetrahydrofuran, chloroform, toluene, ethylene glycol dimethyl ether, and the like.

Examples of R¹ and R² substituents include but are not limited to a methyl group, a phenyl group, a tolyl group, a brominated tolyl group (—C₆H₄CH₂Br), and the like. The aforementioned described examples of substitutents are not meant to limit the scope of the polymer subtitutents and the subsequent polymer that may be used in accordance with the present invention.

Examples of solvents for use in the polymer mixture include but are not limited to xylene, hexane, tetrahydrofuran, chloroform, toluene, ethylene glycol dimethylether, and the like.

The precursor mixture may be applied to at least one surface of an IC component via a spin coating or other casting technique. In this case, a solvent will commonly be used to adjust the rheological properties of the liquid. The mixture may, however, be applied without the use of solvent, for example by spraying, chemical vapor deposition or any other method of direct application of a liquid to a solid surface. Examples of IC components that may have the polymer mixture applied to at least one surface thereon include but are not limited to a an a transistor or a resistor; a copper interconnect; an aluminum interconnect; a porous or non-porous low k dielectric material; an insulating layer, and a barrier layer.

Subsequent to application of the precursor mixture, the carbosilane is heated at a temperature range from about 200° C. to about 450° C. for about 3 hr to about 9 hr to form the capping layer. The formed capping layer is the cured/cross-linked carbosilane derived from heating the carbosilane precursor. When desirable for removing solvent, an intermediary heating step may be inserted or performed before the aforementioned heating. The intermediary heat may be performed at a temperature range from about 120° C. to about 150° C. for a time period of about 20 min to about 45 min. Vacuum could also be used to assist in removing solvent, and this would allow lower temperatures.

The cross-linked carbosilane derived from thermally-induced opening of a precursor polymer or oligomer containing sila- or disilacyclobutane rings has mainly (>90%) or entirely (>97%) C—H, C—C, and Si—C bonds. To the extent that other covalent bonds may be present in the crosslinked carbosilane, they are commonly O—H and Si—O bonds that arise from surface oxidation. A preferred embodiment of this carbosilane is derived from heating of a cyclolinear carbosilane precursor and has the general formula:

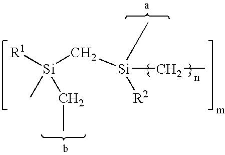

In one embodiment, the polymer of the invention can be used as a capping layer on Cu lines after the chemical mechanical planarization process. A thin layer of PCS can be spun on to the surface, which contains the Cu lines. After curing, a second layer of low K dielectric is applied. This PCS capping will serve as a diffusion barrier and adhesion promoter to enhance electromigration resistance. PCS can also be used as capping layer onto a non-carbosilane low k interlayer dielectric. The term “non-carbosilane, low k dielectric” refers to any material having a dielectric constant below 5 that is not a polymer having mainly or entirely C—H, C—C, and Si—C bonds. The capping layer of the invention can serve as a diffusion barrier and chemical mechanical planarization stop layer.

### EXAMPLES

Examples of the preparation of the precursor mixture and subsequent materials, i.e. a interlayer dielectric or a capping layer (described supra), formed after cross-linking are not explained in depth below and not meant to be limiting to the polymer mixtures and subsequent materials that may be used in accordance with the present invention. Detailed examples of preparation and characterization of the carbosilane of the precursor mixture as well as the cross-linked material may be found in Zhizhong Wu, Jerry P. Papandrea, Tom Apple, and Leonard V. Interrante; Macromolecules 2004, 37, 5257-5264, which is hereby incorporated in its entirety by reference.

### Example 1

Preparation of a Cyclolinear Unsaturated Polycarbosilane (PCS).

In a glove box under an inert N₂ atmosphere, 1.0 g of dry monomer (a) and 10 mg of the second generation Grubbs catalyst (1 wt %) were added to a round bottom flask. The mixture was stirred at room temperature in the glove box until a clear solution resulted, which indicated that the catalyst was completely dissolved in the monomer. The flask was then removed from the glove box, and the contents were stirred under vacuum on a Schlenk line and heated in an oil bath to 40° C.

After one day, the reaction mixture was again taken into the glove box, and an additional aliquot of catalyst was added. The mixture was then stirred at 65° C. until the evolution of ethylene was no longer visible and the stir bar did not stir. The reaction was terminated by exposure to air. The resultant polymer was dissolved in toluene or THF, treated with activated carbon, passed through silica gel column, twice precipitated by pouring into methanol, and then vacuum dried.

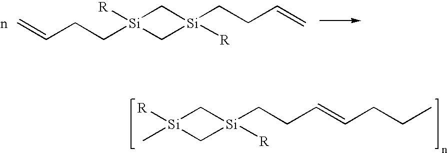

### Example 2

Preparation of a Cyclolinear Saturated Polycarbosilane.
0.2 g (1 mmol) of the unsaturated polymer mixture with 20 ml of xylene was added to a two-necked round bottom flask with a reflux condenser. 0.29 g (2 mmol) of tripropylamine (TPA), and 0.37 g (2 mmol) of p-toluenesulfonhydrazine (TSH) was added to this flask and the mixture was heated at 100° C. in an oil bath for 4 h under nitrogen. The temperature was increased to 110° C. for another 4 h. After removing the solid precipitate, the entire liquid mixture was added to methanol, and the saturated form of the cyclolinear polycarbosilane (CLPCS) was recovered by decantation and dried in vacuum.

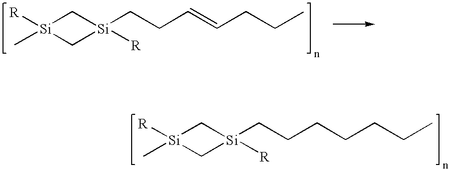

### Example 3

Film Processing for Electrical Measurement.

N type, 4-inch silicon wafers with resistivity of ≦0.02 ohm-cm were used as substrates. After RCA cleaning of the wafers, HMDS was spin-coated at 3000 rpm for 40 sec onto the wafers prior to deposition. The cyclolinear carbosilane polymer was dissolved in xylene at a concentration of 15-20%. The solutions were filtered through a 0.2 mm filter and then spin-deposited onto the pretreated wafers at 3000 rpm for 100 sec, followed by drying in an oven at 140° C. for 30 min. The sample was then placed in a tube furnace and flushed with nitrogen gas for approximately half an hour. The furnace temperature was ramped at a rate of 1.0 C/min to 300° C. in a nitrogen atmosphere and held a temperature for 8 hours before cooling to room temperature. The resultant films were used for electrical property measurements. The measurements demonstrated the use of the polymer films as an interlayer dielectric material and a capping layer. From hereon in, the polymer film prepared by the aforementioned procedure will be referred to as the interlayer dielectric or capping layer interchangeably.

### Example 4

Dielectric Constant Measurement

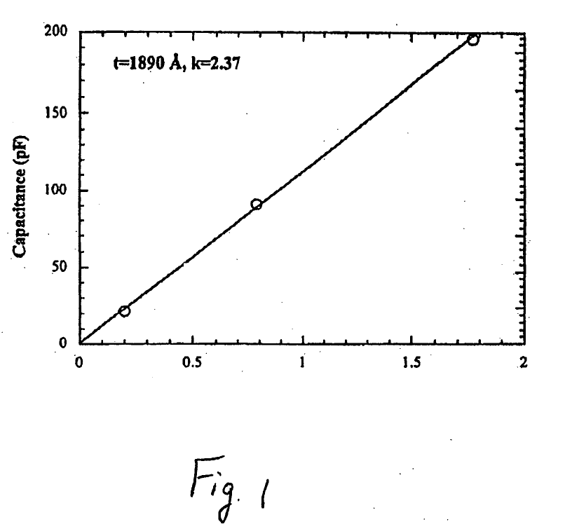

FIG. 1 depicts a plot of the capacitance as a function of Al electrode area for a dielectric measurement of the interlayer dielectric (ILD) in accordance with the present invention. The dielectric constant of the ILD was measured to be 2.3. The dielectric constant was measured from the capacitance data using the equation,
k=Cd/(e0A)
where ε₀ is the permittivity of vacuum (8.85×10⁻¹² C²/Nm²), C is the capacitance, d is the thickness of the sample, and A is the area of the Al electrode. Here, Al electrodes with three different areas, with diameters 0.5, 1, and 1.5 mm, were used to validate the measurement (see FIG. 1). In an embodiment of the present invention, the ILD dielectric constant value is typically about 2.3 to about 2.4. The ILD dielectric constant of the present invention is lower than all of the currently available non-fluorine containing, non-porous dielectric materials available and presently used in IC technology.

### Example 5

Leakage Current Measurement of the ILD.

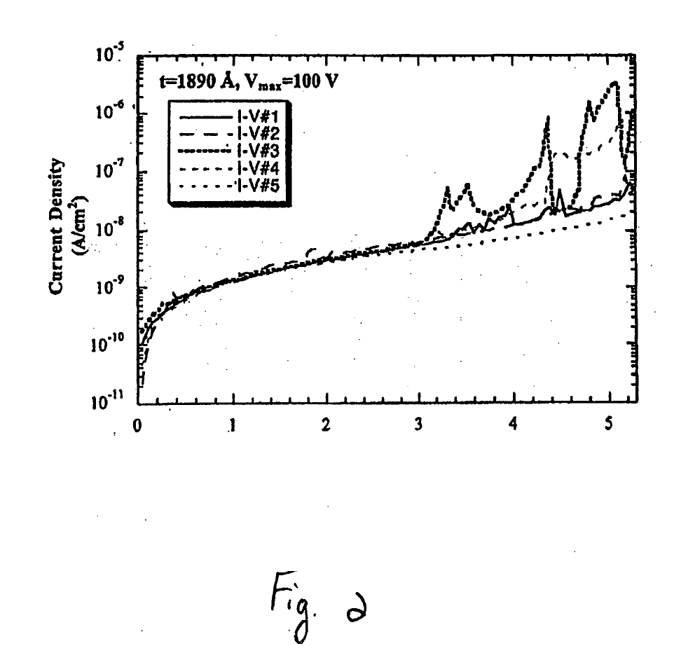

FIG. 2 depicts a plot of current density vs applied field for the ILD in accordance with the present invention. Referring to FIG. 2, leakage current curves for the ILD were determined as a function of the applied field. Five measurements of I-V were taken and show the strong firm base of the extreme value statistics. The intrinsic leakage current curves show that the leakage current densities of the ILD are less than 2×10⁻⁹ A/cm² at the applied field of 1 MV/cm and the average breakdown field for the capping layer was greater than 5 MV/cm.

### Example 6

Copper Diffusion Test on the Capping Layer.

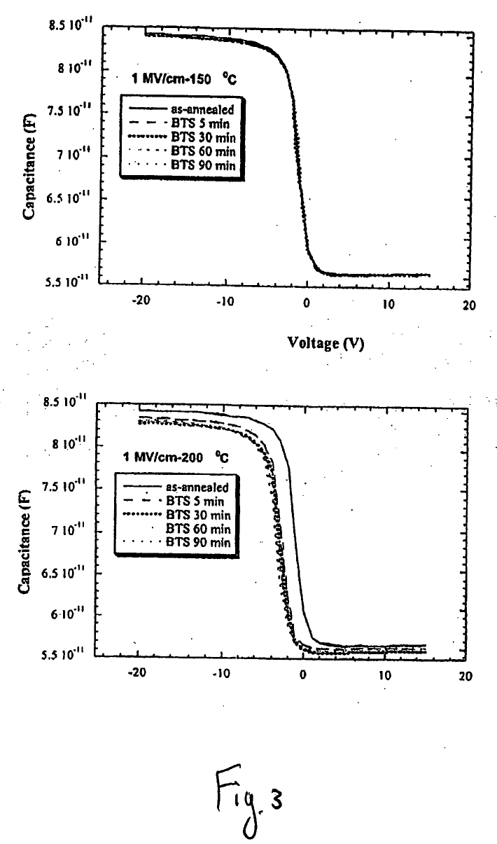

FIG. 3 depicts two plots of a copper/polycarbosilane (PCS) capacitor stressed at two different temperatures in accordance with the present invention. The capacitor sample tested comprised of a Cu/PCS/SiO₂/Si. The Cu represents the metal line, the PCS is the capping layer, and the SiO₂ is the dielectric material deposited on a silicon wafer (Si). Referring to FIG. 3, the Cu/PCS/SiO₂/Si samples showed no capacitance-voltage (C-V) shifts after stressing at a temperature of 150° C. for 90 min, while only a small C-V shift was seen after stressing 200° C., with no further change even for 90 min. The results indicated the capping layer has excellent resistance to copper diffusion under standard Bias Thermal Stress (BTS) test conditions.

### Example 7

A Second Copper Diffusion Test on the Capping Layer.

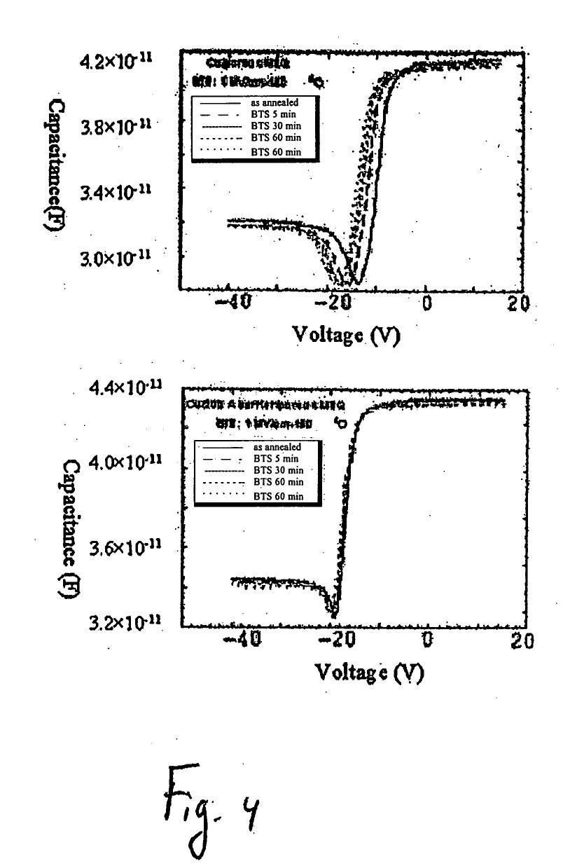

FIG. 4 depicts two stress plots of a capacitor having a polycarbosilane (PCS) capping layer and a capacitor without the PCS capping layer in accordance with the present invention. The capacitor samples tested comprised of a Cu/PCS/MSQ/SiO₂/Si and Cu/MSQ/SiO₂/Si structure. The Cu represents the metal line, the PCS is the capping layer, the MSQ (methylsilsequioxane) is a porous dielectric material, and the SiO₂ is the surface oxide on a silicon wafer (Si).

Referring to FIG. 4, the Cu/MSQ/SiO₂/Si structure showed C-V shifts after stressing at 160° C. for 5 min, while no C-V shift was seen for the Cu/PCS/MSQ/SiO₂/Si sample after 90 min. Examples 6 and 7 demonstrate the use of the PCS capping layer on Cu lines to prevent Cu diffusion at the interface between the capping layer and the Cu line.

An integrated circuit (IC) is presented in accordance with the present invention. The IC comprises: one or more integrated circuit components, and an interlayer dielectric resultant from applying a carbosilane precursor mixture. The precursor mixture comprises:
(i) a polymeric or oligomeric carbosilane of the formula [cyclo-{R¹Si(CH₂)₂SiR²}—(CH₂)ₙ]ₘ wherein
   R¹ is an alkyl, an aryl, or a substituted alkyl or aryl,
   R² is an alkyl, an aryl, or a substituted alkyl or aryl,
   n is 1-10,
   m is >10 and typically >100, and optionally,
(ii) a solvent,
   to at least one surface of the integrated circuit component and heating the polymer mixture to form the interlayer dielectric.

A second integrated circuit (IC) is presented in accordance with the present invention. The IC comprises: an integrated circuit component, and an interlayer dielectric on at least one surface of the integrated circuit component. The interlayer dielectric comprises repeating units of the formula: 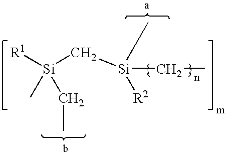
wherein
R¹ is an alkyl, an aryl, or a substituted alkyl or aryl,
R² is an alkyl, an aryl, or a substituted alkyl or aryl,
n is 1-10,
m is >10 and typically >100, and
a and b are points of crosslinking.

What is claimed is:

1. A method for providing an interlayer dielectric comprising:
(a) applying a polymeric or oligomeric carbosilane of the formula [cyclo-{R¹Si(CH₂)₂SiR²}—(CH₂)ₙ]ₘ wherein
R¹ is an alkyl, an aryl, or a substituted alkyl or aryl,
R² is an alkyl, an aryl, or a substituted alkyl or aryl,
n is 1-10,
m is >10;
to an integrated circuit component; and
(b) heating said polymer mixture to form an interlayer dielectric.

2. A method according to claim 1 for providing an interlayer dielectric comprising:
(a) applying a precursor mixture comprising:
(i) a polymer or oligomeric carbosilane of the formula [cyclo-{R¹Si(CH₂)₂SiR²}—(CH₂)ₙ]ₘ wherein
R¹ is an alkyl, an aryl, or a substituted alkyl or aryl,
R² is an alkyl, an aryl, or a substituted alkyl or aryl,
n is 1-10,
m is >10, and
(ii) a solvent,
to an integrated circuit component; and
(b) heating said polymer mixture to form an interlayer dielectric.

3. A method according to claim 2, wherein said applying is chosen from the group consisting of a spin-coating technique, a casting technique, and solution spraying.

4. A method according to claim 2, wherein said solvent is chosen from the group consisting of xylene, hexane, tetrahydrofuran, chloroform, toluene, and ethylene glycol dimethylether.

5. A method according to claim 1, wherein said integrated circuit component is chosen from the group consisting of a transistor, a resistor, a copper interconnect, an aluminum interconnect, a porous dielectric material, a non-porous dielectric material, an insulating layer, a barrier layer, a silicon wafer, a doped silicon wafer, a silicon on sapphire wafer, and a gallium arsenide wafer.

6. A method according to claim 1, wherein said heating is performed at a temperature range from about 200° C. to about 450° C. for about 6 hr to about 9 hr.

7. A method according to claim 1, wherein said alkyl is chosen from the group consisting of methyl, ethyl and propyl.

8. A method according to claim 1, wherein said aryl is chosen from the group consisting of phenyl, tolyl and brominated tolyl.

9. A method according to claim 1, wherein m is greater than 100.

10. A method for capping an integrated circuit component comprising:
(a) applying a polymeric or oligomeric carbosilane of the formula [cyclo-{R¹ Si(CH₂)₂SiR²}—(CH₂)ₙ]ₘ wherein
R¹ is an alkyl, an aryl, or a substituted alkyl or aryl,
R² is an alkyl, an aryl, or a substituted alkyl or aryl,
n is 1-10,
m is >10
to at least one surface of said an integrated circuit component; and
(b) heating said polymer to form a capping layer.

11. A method for capping an integrated circuit component comprising:
(a) applying a mixture comprising:
(i) a polymeric or oligomeric carbosilane of the formula [cyclo-{R¹ Si(CH₂)₂SiR²}-(CH₂)ₙ]ₘ wherein
R¹ is an alkyl, an aryl, or a substituted alkyl or aryl,
R² is an alkyl, an aryl, or a substituted alkyl or aryl,
n is 1-10,
m is >10 and typically >100, and
(ii) a solvent,
to at least one surface of said an integrated circuit component;
(b) drying; and
(c) heating said mixture to form a capping layer.

12. A method according to claim 11, wherein said applying is chosen from the group consisting of a spin-coating technique, a casting technique, a solvent spraying method, and chemical vapor deposition.

13. A method according to claim 11, wherein said solvent is chosen from the group consisting of xylene, hexane, tetrahydrofuran, chloroform, toluene, and ethylene glycol dimethylether.

14. A method according to claim 11, wherein said integrated circuit component is chosen from the group consisting of a transistor, a resistor, a copper interconnect, an aluminum interconnect, a porous dielectric material, a non-porous dielectric material, an insulating layer, and a barrier layer.

15. A method according to claim 11, wherein said integrated circuit component is a component comprising metallic copper.

16. A method according to claim 11, wherein said integrated circuit component is a non-carbosilane interlayer dielectric.

17. A method according to claim 10, wherein said heating is performed at a temperature range from about 200° C. to about 450° C. for about 6 hr to about 9 hr.

18. A method according to claim 10, wherein said alkyl is chosen from the group consisting of methyl, ethyl and propyl.

19. A method according to claim 10, wherein said aryl is chosen from the group consisting of phenyl, tolyl, and brominated tolyl.

20. An integrated circuit comprising:
one or more integrated circuit components; and
an interlayer dielectric resultant from applying a polymer mixture comprising:
(i) a polymeric or oligomeric carbosilane of the formula [cyclo-{R¹Si(CH₂)₂SiR²}—(CH₂)ₙ]ₘ wherein
R¹ is an alkyl, an aryl, or a substituted alkyl or aryl,
R² is an alkyl, an aryl, or a substituted alkyl or aryl,
n is 1-10,
m is >10 and typically >100, and
and, optionally,
(ii) a solvent,
to at least one surface of said an integrated circuit component and, after drying, heating said polymer to form said interlayer dielectric.

21. An integrated circuit comprising:
an integrated circuit component; and
an interlayer dielectric on at least one surface of said integrated circuit component, said interlayer dielectric comprising repeating units of the formula: 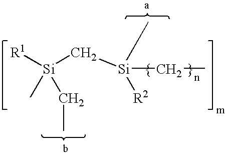
wherein
R¹ is an alkyl, an aryl, or a substituted alkyl or aryl,
R² is an alkyl, an aryl, or a substituted alkyl or aryl,
n is 1-10,
m is >10, and
a and b are points of crosslinking.

22. The integrated circuit according to claim 19, wherein said integrated circuit includes at least one component chosen from the group consisting of a transistor, a resistor, a copper interconnect, an aluminum interconnect, a porous dielectric material, a non-porous dielectric material, an insulating layer, a barrier layer, a silicon wafer, a doped silicon wafer, a silicon on sapphire wafer, and a gallium arsenide wafer.
